(19) United States
(12) Patent Application Publication
(10) Pub. No.: US 2025/0228135 A1
(43) Pub. Date: Jul. 10, 2025

(54) PRODUCING RENEWABLE ENERGY UNDERWATER

(71) Applicant: SUBSEA 7 (US) LLC, Houston, TX (US)

(72) Inventor: Alban Marie Jehan SABIN, Houston (TX)

(21) Appl. No.: 18/684,309

(22) PCT Filed: Aug. 17, 2022
(86) PCT No.: PCT/US2022/040654

§ 371 Date: Feb. 16, 2024

(30) Foreign Application Priority Data
Aug. 18, 2021 (GB) 2111871.6

(51) Int. Cl. H10N 10/13; E21B 33/035; H10N 10/17

(52) U.S. Cl. CPC H10N 10/13; E21B 33/035; H10N 10/17

(57) ABSTRACT

Systems and methods for generating electric power underwater using a thermoelectric generator. At least one wellhead upstream of the generator conveys a flow of fluid at an elevated temperature from a subterranean source to the generator. In one arrangement, at least one other wellhead downstream of the generator conveys to a subterranean formation substantially all of the fluid that flows from the source through the first wellhead. The source and the formation may be a common reservoir, allowing closed-loop operation in which the fluid is recirculated, reheated and repressurised by geothermal energy. In another, open-loop arrangement, the generator cools the fluid by transformation of heat energy to electrical energy and then outputs the cooled fluid to a surface facility. The generator may cool the fluid to just above or below the wax appearance temperature. Cold-flow processing may be used to convey the fluid downstream of the generator under cold-flow conditions.

This invention relates to the production of renewable energy underwater, in particular when generating electricity from a thermal gradient.

Electrical energy is often consumed underwater, for example in subsea processing, heating and/or pumping of well fluids in the subsea oil and gas industry. In that case, it can be convenient to generate electricity close to the point of consumption and hence underwater. Alternatively, or additionally, electrical energy generated underwater may be conveyed to a surface installation such as a platform or FPSO (floating production, storage and offloading vessel), or indeed to a power grid ashore.

Subsea electric generators using fluids from subterranean reservoirs are well known in the art. They may use a motive fluid such as hot geothermal water flowing at high pressure from a water reservoir or aquifer in the earth's crust, or oil or gas flowing with high temperature and pressure from a subsea well. Alternatively, heat can be extracted or exchanged from such fluids and used to heat a different motive fluid. An engine such as a turbine is driven by the energy of the motive fluid, for example operating by the Carnot or Rankine cycle. However, such machines require significant maintenance due to their moving parts, which is a major drawback in deep water.

Subsea electric generators are also known that exploit a thermal gradient between a hot fluid flowing from a source such as a well or reservoir and much colder ambient seawater. For example, in FR 2758009, a thermoelectric generator or TEG is mounted on a subsea pipeline whereas in EP 2314872, a TEG disposed within a subsea canister comprises an electrothermal converter in contact with both a cooling surface and a heating surface of the canister. The cooling surface is cooled by ambient seawater whereas the heating surface is heated by hot fluid flowing from a well. In each case, the TEG generates a flow of electric current due to the Seebeck effect.

In US 2009/217664, a housing comprises an electric generator that can be a TEG or a turbine generator. Hot water from a geothermal reservoir is circulated through the generator. In one embodiment, a closed loop comprises the housing and a borehole in the seabed soil, whereby fluid is reheated by geothermal heat and recirculated to the generator. Similarly, in WO 2016/150651 and DE 102016223611, a TEG is fed by geothermal fluid from a well. Where prior art solutions such as these require disposal of fluid after extracting energy for electricity generation, this is sometimes done by reinjecting the fluid into the same well. In that case, a dedicated wellhead must be drilled.

In DE 102016223611, in particular, a TEG is connected to a subsea oil or gas production well. Water is first separated from the produced fluid before hydrocarbons remaining in the produced fluid are exported to an FPSO. The separated water is then circulated to the TEG before being repressurised and reinjected into the well. Even if used merely as a backup in case of failure of a primary power supply via an umbilical, this proposal is uselessly complex and inefficient. Losses of temperature and pressure during separation decrease the efficiency of power generation; additionally, as pumping to reinject the water consumes energy, more energy is required to recover the pressure loss caused by separation.

Against this background, the invention provides a system for generating electric power underwater, the system comprising: a thermoelectric generator; a first wellhead upstream of the thermoelectric generator, communicating with a subterranean source to convey a flow of fluid from the source to the thermoelectric generator; and a second wellhead downstream of the thermoelectric generator, communicating with a subterranean formation to convey to the formation substantially any and all of the fluid that flows from the source through the first wellhead.

The formation may be in fluid communication with the source. For example, a common reservoir can serve as the source and as the formation. In this way, the fluid can circulate in a closed loop. However, it is also possible for the formation to be distinct from the source. In that case, the formation may be at a lower fluid pressure than the source. Fluid may then flow in a direction from the first wellhead to the second wellhead driven by that fluid pressure differential between the source and the formation. More generally, fluid may flow in a direction from the first wellhead to the second wellhead under convective action driven by a temperature drop across the thermoelectric generator.

The fluid flowing from the source may be predominantly water. The first wellhead and/or the second wellhead may be atop a bore that was previously drilled into the source or the formation and used for hydrocarbon production or exploration.

The invention embraces a corresponding method of generating electric power underwater, the method comprising: conveying a flow of fluid from a subterranean source through a first wellhead to a thermoelectric generator; generating electric power in the thermoelectric generator by virtue of a temperature difference between the fluid and ambient temperature; and conveying substantially all of the fluid that flows from the source and through the thermoelectric generator to a subterranean formation via a second wellhead.

The fluid may be returned to a common reservoir serving as the source and as the formation, or may be returned to the source via the formation. The fluid may be circulated in a closed loop and may be reheated in the formation and/or the source. Alternatively, fluid in the formation may be isolated from fluid in the source.

Flow from the source through the thermoelectric generator and to the formation may be driven by a difference in fluid pressure between the source and the formation and/or by convective action arising from a temperature drop across the thermoelectric generator.

Fluid may be extracted from the source through a bore that was previously drilled into the source for hydrocarbon production or exploration. Similarly, fluid may be injected into the formation through a bore that was previously drilled into the formation for hydrocarbon production or exploration.

The inventive concept extends to another system for generating electric power underwater, the system comprising a thermoelectric generator communicating with a subterranean source to receive hydrocarbon fluid from the source at an elevated temperature and to cool the fluid by transformation of heat energy to electrical energy in the thermoelectric generator. The system may be an open-loop system. For example, an outlet of the thermoelectric generator may be in fluid communication with a surface facility to output the cooled fluid to the surface facility.

The system may further comprise a cold-flow factory including a heating system for intermittent removal and entrainment of material deposited from the fluid cooled by the thermoelectric generator.

The system may further comprise an injection system for injection of chemicals into the fluid, those chemicals being for inhibiting formation of wax, hydrates or asphaltenes.

The system may further comprise a separation system for separating water from the fluid.

Correspondingly, the inventive concept may also be expressed as a method of generating electric power underwater, the method comprising: conveying a hydrocarbon fluid from a subterranean source to a thermoelectric generator at an elevated temperature; generating electric power in the thermoelectric generator by virtue of a temperature difference between the fluid and ambient temperature; cooling the fluid by transformation of heat energy to electrical energy in the thermoelectric generator; and outputting the cooled fluid from the thermoelectric generator. The cooled fluid may be conveyed to a surface facility, having been cooled by, for example, 90° C. or more in the thermoelectric generator.

The fluid may be cooled to below a wax appearance temperature of the fluid, followed by cold-flow processing for cold-flow transport of the cooled fluid downstream from the thermoelectric generator.

The fluid may instead be cooled to just above a temperature at which waxes, hydrates or asphaltenes will gel, precipitate or coalesce in the fluid. Chemicals may be injected into the fluid to inhibit formation of waxes, hydrates or asphaltenes. Water may also be separated from the fluid.

In summary, the invention provides a source of renewable energy that employs non-rotating technology to generate electricity in remote or deep-water subsea locations. To do so, the invention employs one or more TEGs that use the Seebeck effect to convert heat transfer, due to a temperature differential, into electricity. By scaling up today's use of TEGs, and moving the technology to deep water, it is possible to generate a significant quantity of renewable and sustainable electrical energy using geothermal energy from subsurface reservoirs. Thus, the invention provides sustainable electricity generation for powering hardware in deep-water fields and pipeline systems. The invention may also provide a source of renewable energy to offshore platforms or FPSOs, or indeed to consumers on land.

The invention may be used in various applications. For example, when an exploration or appraisal well has been drilled but a reservoir has been found to be unsuitable for hydrocarbon production, the well can be still used if a good reservoir of water has been contacted. The operator can then account for the cost of drilling the well in a different way, without having to write off that cost. Analogously, the invention also finds benefit where hydrocarbons in a reservoir with multiple perforations or boreholes have been depleted by production but the reservoir is still well-supported by an aquifer and has sustained fluid pressure.

The invention also finds benefit where it is desirable to reduce the temperature of a production fluid. For example, production fluid may otherwise be too hot to allow the use of a conventional insulation system, such as in production of hydrocarbons from the Norphlet formation in the Gulf of Mexico.

It may also be desirable to cool and separate the phases of a production fluid for ‘cold flow’ processing, in which the risk of unintended wax deposition is mitigated by cooling the fluid to force wax deposition in a flowline. Periodic heating causes the wax layer to melt off and fall into the wellstream. There, the wax is entrained to form a slurry that can be transported under cold-flow conditions, typically at a temperature below 50° C. This reduces the need for insulation or heating of a pipeline to keep the production fluid above the wax appearance temperature or WAT.

Embodiments of the invention provide a device to generate electric power underwater, the device comprising: a thermoelectric generator unit laid on the seabed, which generator may for example use the Seebeck effect; and at least two fluid connections between the thermoelectric generator and distinct subsea wellheads. For example, a first fluid connection may be an inlet from a subsea wellhead and a second fluid connection may be an outlet toward another distinct subsea wellhead.

The generator may employ a cold source being ambient seawater and a hot source being fluid from the inlet. That fluid may for example be, or may predominantly comprise, pressurised water or hydrocarbons flowing from a subterranean subsea reservoir.

The outlet wellhead may be an injection wellhead to inject the fluid into a subterranean subsea reservoir, after power generation and cooling. That reservoir may be fluidly connected to, or may be the same as, the reservoir for the fluid of the hot source. The reservoir may conveniently be used for containment of the fluid, for heating by geothermal heat, and for circulation of fluid between the first and second wellheads. Advantageously, temperature and pressure gradients may be sufficient for the fluid to circulate without a pump, although a pump could be used as secondary or auxiliary driver of fluid flow. Even if a pump is used as a primary driver of fluid flow, convection and pressure gradients may assist the flow and therefore reduce the power consumed by the pump.

Embodiments of the invention also implement a method to produce electric power underwater, the method comprising: installing a thermoelectric generator on the seabed; fluidly connecting at least one inlet of the thermoelectric generator to a first wellhead communicating with a subterranean reservoir; and fluidly connecting at least one outlet of the thermoelectric generator to a second wellhead communicating with the same subterranean reservoir.

The method may also comprise pressurising fluid before injection into the reservoir. For example, pumping may be performed by an electric pump or a jet pump. A jet pump may, for example, use seawater as a motive fluid.

Embodiments of the invention also provide a device to generate electric power underwater, the device comprising: a thermoelectric generator unit laid on the seabed; at least one fluid connection between an inlet of the thermoelectric generator and one or more subsea wellheads; and at least one fluid connection between an outlet of the thermoelectric generator and a surface facility; wherein the thermoelectric generator effects cooling of the fluid.

The fluid may, for example, be cooled down to the lowest possible temperature for it to be transported to the surface facility without gelling, precipitating or coalescing into a solution or plug of wax, hydrates or asphaltenes. The fluid may be processed before or during cooling in the device to be transported in cold flow, for example by injection of inhibitor chemicals and/or by water/oil separation.

In summary, the invention contemplates various systems and methods for generating electric power underwater using a thermoelectric generator. At least one wellhead upstream of the generator conveys a flow of fluid at an elevated temperature from a subterranean source to the generator.

In one arrangement, at least one other wellhead downstream of the generator conveys to a subterranean formation substantially all of the fluid that flows from the source through the first wellhead, irrespective of the nature or type of the fluid. The source and the formation may be a common reservoir, allowing closed-loop operation in which the fluid is recirculated, reheated and repressurised by geothermal energy.

In another, open-loop arrangement, the generator cools the fluid by transformation of heat energy to electrical energy and then outputs the cooled fluid to a surface facility. The generator may cool the fluid to just above or below the wax appearance temperature. Cold-flow processing may be used to convey the fluid downstream of the generator under cold-flow conditions.

In order that the invention may be more readily understood, reference will now be made, by way of example, to the accompanying drawings in which:

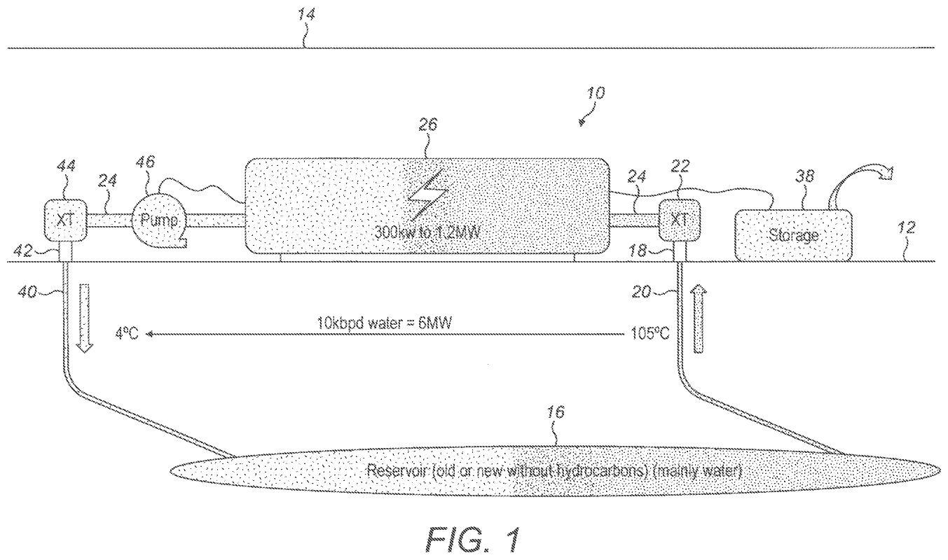

FIG. 1 is a schematic side view of a subsea installation of the invention in fluid communication via separate wellheads with a common subterranean reservoir;

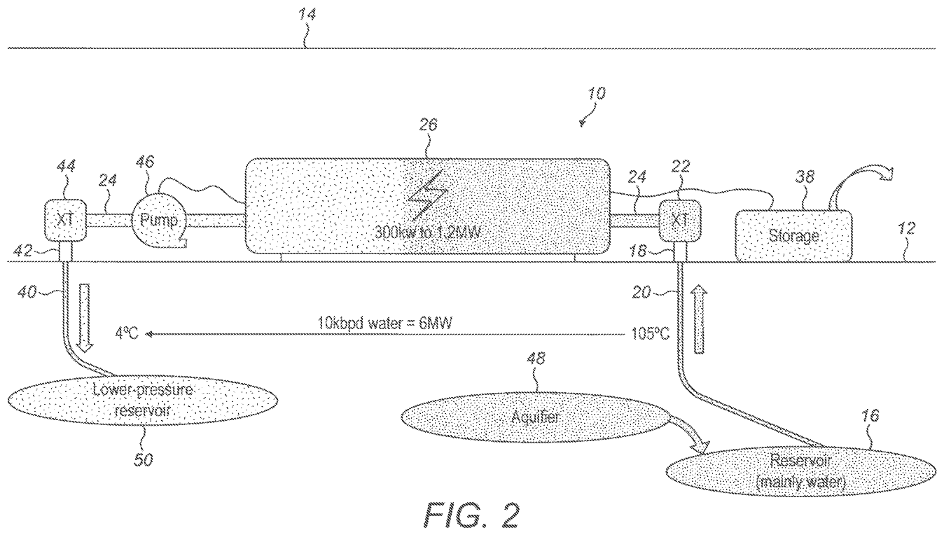

FIG. 2 is a schematic side view of a subsea installation of the invention in fluid communication via separate wellheads with respective, separate subterranean reservoirs;

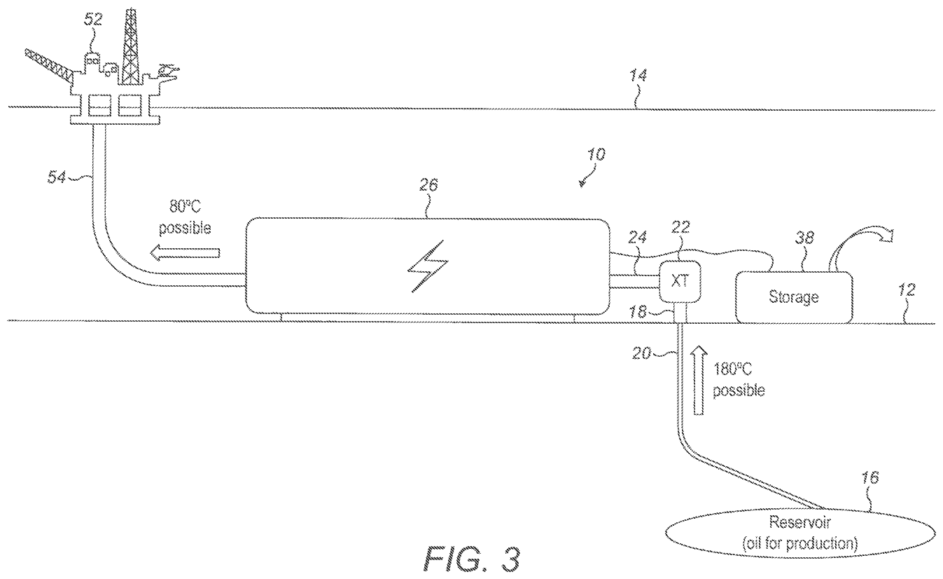

FIG. 3 is a schematic side view of a subsea installation of the invention when cooling production fluid flowing between a subterranean well and a surface installation;

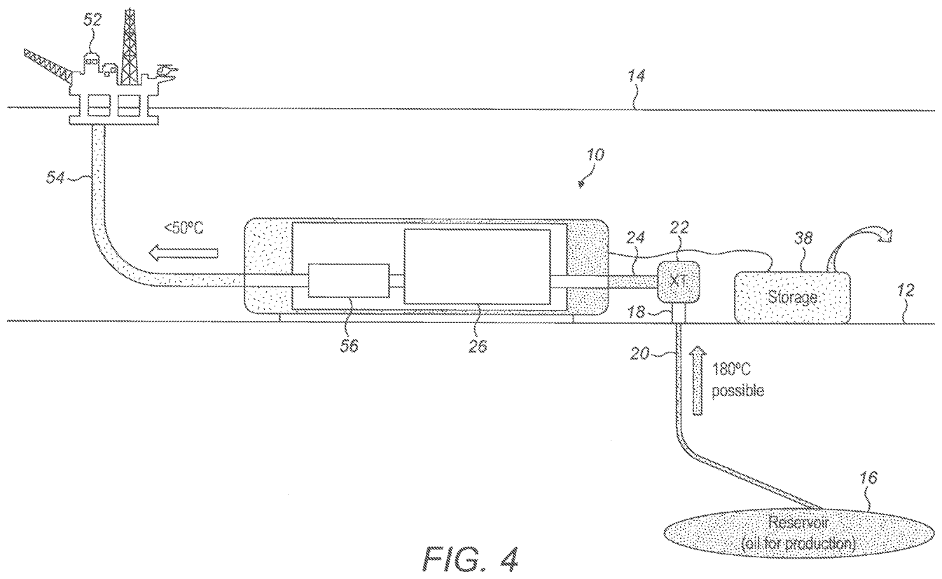

FIG. 4 is a schematic side view of a subsea installation of the invention effecting cold flow of production fluid from a subterranean well to a surface installation;

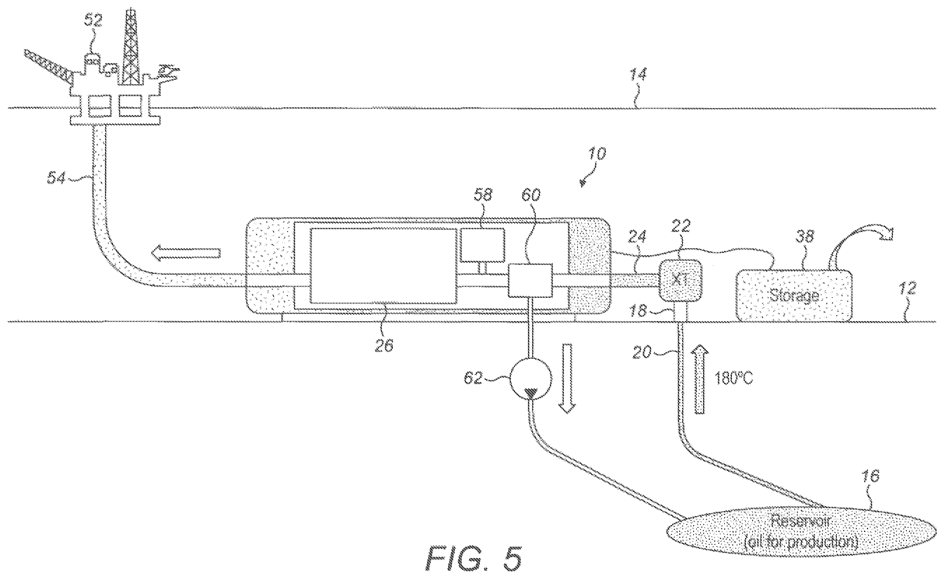

FIG. 5 corresponds to FIG. 3 but shows provisions for water separation and chemical injection; and

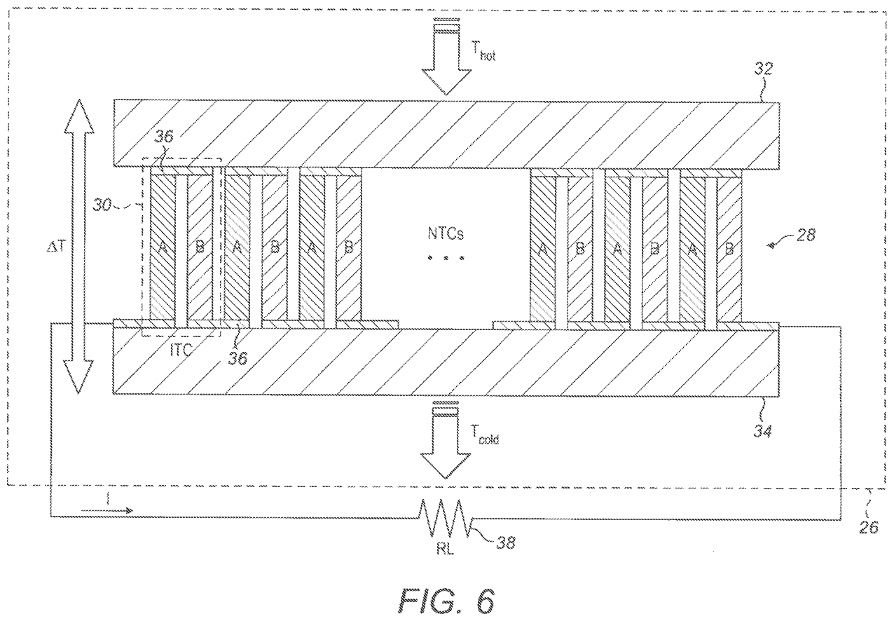

FIG. 6 is a schematic view of a thermopile arrangement that may be used to generate electricity within the installations of FIGS. 1 to 5.

FIGS. 1 to 5 of the drawings, in which like numerals are used for like features, show subsea installations 10 of the invention at a subsea location such as the seabed 12. The installations 10 may be located in deep water, for example at a depth of up to 3000 m beneath the surface 14.

In each case, the installation 10 receives a hot, pressurised fluid from a subterranean formation or reservoir 16 beneath the seabed 12. For this purpose, the installation 10 is in fluid communication with the reservoir 16 via a wellhead 18 of a bore or well 20 surmounted by a conventional fluid-handling structure such as a Christmas tree 22. A subsea conduit 24 extends across the seabed 12 from the Christmas tree 22 to, and through, the installation 10.

The pressure and convection of the hot fluid in the reservoir 16 may be such that the fluid will flow into and through the installation 10 without additional pumping assistance, although a pump may be provided in the conduit 24 on the inlet side of the installation 10 if required.

In each case, the installation 10 comprises a TEG unit 26 that generates electricity by virtue of a temperature differential, or ΔT, between the flow of hot fluid received from the reservoir 16 and the cold ambient seawater. The internal arrangement of the TEG unit 26 is exemplified in FIG. 6, which shows a thermopile 28 comprising several thermocouples (TC) 30 connected in series.

The thermocouples 30 are disposed between a hot side 32 of the thermopile 28 in thermal contact with the conduit 24 carrying a flow of the hot fluid and a cold side 34 of the thermopile 28 in thermal communication with the ambient seawater. Specifically, each thermocouple 30 comprises two dissimilar electrical conductors A, B joined by a metallic connector defining an electrical junction 36. The conductors A, B extend between the hot and cold sides 32, 34 of the thermopile 28 such that the successive junctions 36 of the series alternate between the hot and cold sides 32, 34.

Thermally- and electrically-insulating material may be disposed between the hot and cold sides 32, 34 of the thermopile 28, between and around the conductors A, B of the thermocouples 30. However, such insulation has been omitted from FIG. 6 for clarity.

As the hot fluid flowing through the conduit 24 heats the hot side 32 of the thermopile 28, the ΔT between the hot and cold sides 32, 34 of the thermopile 28 causes each thermocouple 30 to produce a respective voltage. The thermopile 28 therefore produces an aggregate output voltage being the sum of the voltages of the individual thermocouples 30 connected in series. That output voltage drives a current I through an external electrical load R_{L} 38, such as other subsea equipment or a surface installation. In FIGS. 1 to 4, the external load 38 is exemplified by subsea electrical storage, which may for example employ an arrangement of batteries or hydraulic accumulators.

Thus, as the hot fluid flowing through the conduit 24 heats the hot side 32 of the thermopile 28, heat energy in the fluid is converted into electrical energy. In consequence, the temperature of the hot fluid will fall as the flow in the conduit 24 traverses the thermopile 28. In principle, the temperature of the hot fluid can fall to or approach the temperature of the ambient seawater, which is typically 4° C. near the seabed 12 in deep water. To maintain a consistent ΔT between the hot and cold sides 32, 34 of the thermopile 28 along the length of the thermopile 28, the hot fluid in the conduit 24 could be directed to flow across all of the thermocouples 30 in parallel. Although not shown, two or more thermopiles 28 can be combined in series or in parallel, as needed.

Referring now specifically to FIG. 1, the reservoir 16 shown in this example mainly contains water. For example, the reservoir 16 could be a depleted hydrocarbon well whose production phase has ended or an exploration or appraisal well that has been deemed unsuitable for hydrocarbon production. Commonly, at least one separate secondary bore or well 40 will communicate with such a reservoir 16 and so is available for use by the invention without having to be drilled for that purpose.

In this case, the conduit 24 extends through the TEG unit 26 containing at least one thermopile 28 like that shown in FIG. 6. The conduit 24 then exits the TEG unit 26 and extends across the seabed 12 to convey the now-cooled fluid back to the reservoir 16 through the secondary bore or well 40. A secondary wellhead 42 is atop the secondary bore or well 40 and is again surmounted by a conventional fluid-handling structure such as a Christmas tree 44. The arrangement of FIG. 1 is therefore a closed-loop or closed-circuit system in which substantially all fluid from the well is recirculated and no fluid is removed from the system.

FIG. 1 shows the option of a pump 46 in the conduit 24 downstream of the TEG unit 26 for pressurising the cooled fluid to an elevated pressure suitable for reinjection into the reservoir 16. Returning the fluid to the reservoir 16 in this way avoids pollution of the surrounding seawater and maintains pressure in the reservoir 16, which can re-heat the fluid. In principle, however, convective circulatory flow between the TEG unit 26 and the reservoir 16 may be possible via the conduit 24 with or without assistance from the pump 46, or could at least reduce the power required by the pump 46.

It is estimated that a typical TEG unit 26 could produce electrical power of 300 kW to 1.3 MW. For example, a flow of 10,000 barrels per day of water entering the TEG unit 26 at a temperature of 105° C. and exiting the TEG unit 26 at a temperature of 4° C. (hence with a ΔT of 101° C.) can, on average, make 6 MW of power available for conversion by the TEG unit 26 into electricity. The efficiency of the TEG unit 26 in this respect is estimated to be in the range 5% to 20%.

Turning to FIG. 2, this shows another arrangement in which no fluid is removed from the system but in this example the fluid is instead moved from one location, or source, to another location, or destination. Here, the reservoir 16 again contains mainly water but, in this instance, the reservoir 16 is in fluid communication with an aquifer 48 that maintains high fluid pressure in the reservoir 16. Also, the conduit 24 downstream of the TEG unit 26 conveys the now-cooled fluid to a secondary formation or reservoir 50 through the secondary wellhead 42 and the secondary bore or well 40.

The secondary reservoir 50 is isolated from, and hence not in fluid communication with, the reservoir 16 and may contain fluid at a lower pressure than the reservoir 16, for example by being at a different elevation, closer than the reservoir 16 to the seabed 12. The pressure differential between the reservoir 16 and the secondary reservoir 50 could be sufficient to drive flow through the installation 10 without the assistance of the pump 46, or could at least reduce the power required by the pump 46.

In FIGS. 3 and 4, the reservoir 16 contains hydrocarbons such as oil in an amount sufficient for production. Thus, the fluid flowing through the TEG unit 26 in this instance is a production fluid containing oil. The production fluid is conveyed to a surface installation 52 such as a platform via a riser 54 downstream of the TEG unit 26, meaning that FIGS. 3 and 4 show open-loop or open-circuit systems in which a substantial volume of fluid is removed from the system. In each case, the production fluid exits the reservoir 16 at say 180° C. in these examples.

In FIG. 3, the TEG unit 26 is arranged to effect a ΔT of approximately 100° C., hence reducing the temperature of the production fluid to about 80° C. A lower temperature such as this is more practical for effective thermal insulation of the riser 54.

In FIG. 4, the TEG unit 26 is integrated with or upstream of a cold flow factory 56. The cold flow factory 56 mitigates the risk of uncontrolled wax deposition by cooling the flow of production fluid to below the wax appearance temperature (WAT), interspersed with intermittent heating to cause deposited wax to disintegrate and to be entrained in the flow. The TEG unit 26 may be arranged to effect a ΔT that is sufficient to reduce the temperature of the production fluid to below the WAT. The TEG unit 26 will at least cool the production fluid to a temperature closer to the WAT so that the cold flow factory 56 can achieve cold flow conditions more easily. The cold flow factory 56 also has a heating facility to disintegrate deposited wax.

The thermal energy, Q, available for power generation by reducing the temperature of a mass of a given fluid is given by the equation:

$$Q = m c Δ T$$

where m is the mass of the fluid;
   c is the specific heat of the fluid; and
   ΔT is the temperature difference.

If, for example: m=1,590,000 kg (corresponding to 10,000 barrels of water); c=4185 J/kg° C., being characteristic of water; and ΔT=90° C.; then Q=approximately 166 MWh. If a steady flow over the course of one day totals that mass of fluid, then power of 6.91 MW (166 MWh/24 h) is available for conversion to electrical power in the TEG unit 26. If the power conversion efficiency of the TEG unit 26 is nominally 10%, then an electrical power output of 0.691 MW or 691 kW may be expected.

It will be apparent from the equation above that the greater the ΔT, the greater the power that can be generated by a TEG unit 26 of a given efficiency. For production fluid of a given input temperature, it is therefore desirable to cool the fluid as much as possible in the TEG unit 26. However, as this has the effect of reducing the output temperature of the fluid to be transported to the surface facility, there is a practical limit to the extent of cooling. This limit is that the fluid should not be cooled below a temperature at which wax, hydrates or asphaltenes are likely to gel, precipitate or coalesce to the extent that a flowline or riser could become plugged.

To reduce the risk of plugging while maximising the ΔT, production fluid may be processed before, during or after cooling in the TEG unit 26, for example by injection of inhibitor chemicals and/or by separation of water from oil or gas. These possibilities are shown in FIG. 5, in the form of chemical injection apparatus 58 and a water separation system 60 which, in this example, are both disposed upstream of the TEG unit 26 but could instead be downstream of the TEG unit 26 or integrated with it. Processing the production fluid in these ways could be a precursor to conveying the production fluid in cold-flow conditions with additional provisions such as the cold-flow factory 56 shown in FIG. 4.

In the example shown in FIG. 5, a pump 62 reinjects water separated from hydrocarbons into the reservoir 16. The separated water could instead be injected into a separate reservoir, such as the secondary reservoir 50 shown in FIG. 2, or could be cleaned and then released into the surrounding sea.

1. A system for generating electric power underwater, the system comprising:
a thermoelectric generator;
a first wellhead upstream of the thermoelectric generator, communicating with a subterranean source to convey a flow of fluid from the source to the thermoelectric generator; and
a second wellhead downstream of the thermoelectric generator, communicating with a subterranean formation to convey to the formation substantially any and all of the fluid that flows from the source through the first wellhead.

2. The system of claim 1, wherein the formation is in fluid communication with the source.

3. The system of claim 1, wherein a common reservoir serves as the source and as the formation.

4. The system of claim 1, arranged such that the fluid circulates in a closed loop.

5. The system of claim 1, wherein the formation is distinct from the source.

6. The system of claim 5, wherein the formation is at a lower fluid pressure than the source.

7. The system of claim 6, arranged such that the fluid flows in a direction from the first wellhead to the second wellhead driven by said fluid pressure differential between the source and the formation.

8. The system of claim 1, arranged such that the fluid flows in a direction from the first wellhead to the second wellhead under convective action driven by a temperature drop across the thermoelectric generator.

9. The system of claim 1, wherein the fluid flowing from the source is predominantly water.

10. The system of claim 1, wherein the first wellhead is atop a bore previously drilled into the source and used for hydrocarbon production or exploration.

11. The system of claim 1, wherein the second wellhead is atop a bore previously drilled into the formation and used for hydrocarbon production or exploration.

12. A method of generating electric power underwater, comprising:
conveying a flow of fluid from a subterranean source through a first wellhead to a thermoelectric generator;
generating electric power in the thermoelectric generator by virtue of a temperature difference between the fluid and ambient temperature; and
conveying substantially all of the fluid that flows from the source and through the thermoelectric generator to a subterranean formation via a second wellhead.

13. The method of claim 12, comprising returning the fluid to a common reservoir serving as the source and as the formation.

14. The method of claim 12, comprising returning the fluid to the source via the formation.

15. The method of claim 12, comprising circulating the fluid in a closed loop.

16. The method of claim 12, comprising reheating the fluid in the formation.

17. The method of claim 12, comprising isolating fluid in the formation from fluid in the source.

18. The method of claim 17, comprising driving flow from the source through the thermoelectric generator and to the formation by virtue of a difference in fluid pressure between the source and the formation.

19. The method of claim 12, comprising driving flow from the source through the thermoelectric generator and to the formation by convective action arising from a temperature drop across the thermoelectric generator.

20. The method of claim 12, comprising extracting fluid from the source through a bore previously drilled into the source for hydrocarbon production or exploration.

21. The method of claim 12, comprising injecting fluid into the formation through a bore previously drilled into the formation for hydrocarbon production or exploration.

22. A system for generating electric power underwater, the system comprising a thermoelectric generator communicating with a subterranean source to receive hydrocarbon fluid from the source at an elevated temperature and to cool the fluid by transformation of heat energy to electrical energy in the thermoelectric generator.

23. The system of claim 22, being an open-loop system.

24. The system of claim 22, wherein an outlet of the thermoelectric generator is in fluid communication with a surface facility to output the cooled fluid to the surface facility.

25. The system of claim 22, further comprising a cold-flow factory including a heating system for intermittent removal and entrainment of material deposited from the fluid cooled by the thermoelectric generator.

26. The system of claim 22, further comprising an injection system for injection of chemicals into the fluid, those chemicals being for inhibiting formation of wax, hydrates or asphaltenes.

27. The system of claim 22, further comprising a separation system for separating water from the fluid.

28. A method of generating electric power underwater, the method comprising:
conveying a hydrocarbon fluid from a subterranean source to a thermoelectric generator at an elevated temperature;
generating electric power in the thermoelectric generator by virtue of a temperature difference between the fluid and ambient temperature;
cooling the fluid by transformation of heat energy to electrical energy in the thermoelectric generator; and
outputting the cooled fluid from the thermoelectric generator.

29. The method of claim 28, comprising outputting the cooled fluid to a surface facility.

30. The method of claim 28, comprising cooling the fluid to below a wax appearance temperature of the fluid.

31. The method of claim 30, comprising cold-flow processing for cold-flow transport of the cooled fluid downstream from the thermoelectric generator.

32. The method of claim 28, comprising cooling the fluid to just above a temperature at which waxes, hydrates or asphaltenes will gel, precipitate or coalesce in the fluid.

33. The method of claim 28, comprising injecting chemicals into the fluid to inhibit formation of waxes, hydrates or asphaltenes.

34. The method of claim 28, comprising separating water from the fluid.

35. The method of claim 28, comprising cooling the fluid by at least 90° C. in the thermoelectric generator.
